(19) United States
(12) Patent Application Publication
(10) Pub. No.: US 2026/0231380 A1
(43) Pub. Date: Aug. 6, 2026

(54) COOLING SOLUTIONS WITH ANISOTROPIC THERMAL CONDUCTIVITY

(71) Applicant: Toyota Motor Engineering & Manufacturing North America, Inc., Plano, TX (US)

(72) Inventors: Feng Zhou, Ann Arbor, MI (US); Ercan Mehmet Dede, Ann Arbor, MI (US); Shailesh Joshi, Ann Arbor, MI (US)

(73) Assignee: Toyota Motor Engineering & Manufacturing North America, Inc., Plano, TX (US)

(21) Appl. No.: 19/042,234

(22) Filed: Jan. 31, 2025

(51) Int. Cl. H05K 7/20; B33Y 10/00; B33Y 40/20

(52) U.S. Cl. CPC H05K 7/209; B33Y 10/00; B33Y 40/20; H05K 7/20409

(57) ABSTRACT

Devices and methods for thermal management are provided. The device comprises one or more thermally conducting regions, and each thermal conducting region includes a composite material containing thermally conductive fillers that are capable of being oriented in a direction by applying an external force. The method includes steps of forming each thermal conducting region and thereby forming a thermal management device with designed anisotropic thermal conductivity.

### TECHNICAL FIELD

The present application is generally related to apparatus and methods for cooling power devices.

### BACKGROUND

Efficient thermal management is essential for maintaining the performance of power devices. In highly integrated power devices, such as integrated electronics or photonics, the components are closely packed, and each component generates a significant amount of heat. Effective dissipation and spreading of heat generated from each component are particularly important to ensure each component is kept with its operational temperature range, maintain the overall performance of the integrated power devices, and prevent catastrophic failure due to overheating of one or more components. Accordingly, there is a need for effective heat dissipation and spreading mechanisms for highly integrated power devices.

### SUMMARY

Embodiments disclosed herein address the need by providing a thermal management device with designed anisotropic thermal conductivity, capable of directing heat dissipation and spreading via engineered thermal conducting paths.

In one or more embodiments, a thermal management device for cooling a power device is provided. The thermal management device may include a thermal interface material, a heat sink, or both. The thermal interface material or the heat sink or both may independently have one or more of thermal conducting regions. Each thermal conducting region independently comprises a composite material, and the composite material includes a matrix material and a plurality of thermally conductive fillers. For each thermal conducting region, the plurality of thermally conductive fillers are oriented in a direction, generating an anisotropic thermal conductivity; and the plurality of thermally conductive fillers are thermally coupled to form a plurality of thermal conducting paths, operable to conduct heat from one or more heat sources of the power device.

In other embodiments, a method of forming the thermal management device for cooling a power device is provided. The method includes a step of depositing a thermal interface material, a heat sink, or both on to the power device, wherein a first portion of the thermal interface material, the heat sink, or both independently comprise a composite material comprising a matrix material and a plurality of thermally conductive fillers. The method further includes a step of applying a first external force to the first portion of the thermal interface material, the heat sink, or both, and a step of orienting, within the first portion of the thermal interface material, the heat sink, or both, the plurality of thermally conductive fillers in a first direction. The method further includes a step of curing the first portion of the thermal interface material, the heat sink, or both, and thereby forming, within the first portion of the thermal interface material, the heat sink, or both, one or more thermal conducting regions comprising a first anisotropic thermal conductivity in the first direction.

These and other features, aspects, and advantages of the present invention will become better understood with reference to the following description and the appended claims.

### BRIEF DESCRIPTION OF THE DRAWINGS

Though the specification concludes with claims particularly pointing out and distinctly claiming the invention, it is believed that the present invention will be better understood from the following description taken in conjunction with the accompanying drawings, in which:

FIG. 1 illustrates an example method of forming a thermal management device, according to embodiments disclosed and described herein;

FIG. 2 illustrates another example method of forming a thermal management device, according to embodiments disclosed and described herein;

FIG. 3 illustrates an example method of forming a thermal conducting region within an example thermal management device, according to embodiments disclosed and described herein;

FIG. 4 illustrates another example method of forming a thermal conducting region within an example thermal management device, according to embodiments disclosed and described herein;

FIG. 5 illustrates an example thermal management device, in which the thermal interface material has a plurality of thermal conducting regions, according to embodiments disclosed and described herein;

FIG. 6 illustrates an example configuration of thermally conductive fillers for each thermal conducting region within a thermal interface material, according to embodiments disclosed and described herein;

FIG. 7 illustrates a cross-sectional view of an example configuration of thermally conductive fillers for each thermal conducting region within a thermal management device, according to embodiments disclosed and described herein;

FIG. 8 illustrates a top view of an example configuration of thermally conductive fillers within a thermal management device, according to embodiments disclosed and described herein;

FIG. 9 illustrates an example thermal management device, in which the heat sink has a plurality of thermal conducting regions, according to embodiments disclosed and described herein;

FIG. 10 illustrates an example configuration of thermally conductive fillers for each thermal conducting region within a heat sink, according to embodiments disclosed and described herein;

FIG. 11 illustrates an example thermal management device, in which both the thermal interface material and the heat sink have a plurality of thermal conducting regions, according to embodiments disclosed and described herein;

FIG. 12 illustrates an example configuration of thermally conductive fillers for each thermal conducting region within a thermal interface material and a heat sink, according to embodiments disclosed and described herein;

FIG. 13 illustrates an example thermal management device for a power device having multiple heat sources, according to embodiments disclosed and described herein;

FIG. 14 illustrates an example configuration of thermally conductive fillers for each thermal conducting region of an example thermal management device designed for a power device having multiple heat sources, according to embodiments disclosed and described herein;

FIG. 15 illustrates an example thermal management device that includes a thermal insulating region, according to embodiments disclosed and described herein; and

FIG. 16 illustrates an example configuration of thermal conducting regions and thermal insulating regions, according to embodiments disclosed and described herein.

### DETAILED DESCRIPTION

Embodiments disclosed and described herein are related to thermal management devices with designed anisotropic thermal conductivity, and methods of forming the thermal management devices for highly integrated power devices.

Conventionally, a thermal management device, such as a heat sink, is made by bulk metal with high thermal conductivity like copper or aluminum. However, in highly integrated electronics or photonics, heat-generating components are closely packed, and each component has a specific operating temperature range. Heat from one component can interfere with neighboring components, causing thermal noise and signal distortion. To effectively manage the thermal requirements of each component, it may be desirable to form thermal management devices with designed anisotropic thermal conductivity tailored according to the layout of the integrated power device and the requirements of each component.

The present disclosure includes a thermal management device having a composite material that contains thermally conductive fillers capable of being aligned in one or more directions, resulting in anisotropic thermal conductivity along the direction in which the thermally conductive fillers are aligned. More particularly, the composite material may contain multiple discrete thermal conducting regions, and thermally conductive fillers in each thermal conducting region are variably aligned, resulting in multiple discrete thermal conducting regions with varying anisotropic thermal conductivity. The thermal conducting regions with varying anisotropic thermal conductivity may be thermally coupled to form thermal conducting paths that direct the dissipation and spreading of heat. As described in more detail herein, the anisotropic thermal conductivity of each thermal conducting region may be configured according to the layout of an individual integrated power device and/or the requirements of each component within the device.

The disclosed thermal management devices may be formed by additive manufacturing (AM) techniques, such as a three-dimensional (3D) printing process. AM techniques may be specifically advantageous for the formation of the thermal management devices disclosed and described herein. In particular, a thermal management device with anisotropic thermal conductivity designed according to the layout of components within a power device may be too complex to be formed using conventional methods. However, by utilizing AM techniques, it may be possible to form more intricate thermal conducting paths within a thermal interface material, a heat sink, or both to effectively guide the dissipation and spreading of heat generated from each component, according to the layout of an individual power device and/or each component's specific thermal management requirements.

Furthermore, AM techniques may allow for the formation of a thermal management device with complex geometries that seamlessly blend different materials. This provides additional flexibility in the design of a thermal management device to meet the specific needs of each heat-generating component within an integrated electronic or photonics. The ability to incorporate different materials enables the formation of a thermal management device with thermal conducting regions of varying materials and compositions, tailoring the thermal conductivity to meet varying operating temperature range requirements. For example, in some embodiments, a thermal management device having both thermal conducting regions and thermal insulating regions that are substantially free of thermally conductive fillers may be formed using AM techniques. In these embodiments, the thermal insulating regions are disposed between the thermal conducting regions thermally coupled to different heat-generating components and form a thermal barrier. The thermal barrier enables the dissipation of heat generated from different components through distinct thermal conducting paths, thereby reducing thermal interference between components.

Embodiments describing AM workflow for integrating the thermal management devices and integrated power device using 3D printed composite material with configured anisotropic thermal conductivity are provided. Example designs of the thermal management devices for various component layouts and requirements are also provided. Accordingly, as described in more detail herein, the present disclosure provides methods for thermal management of highly integrated power devices, solving the need for enhanced heat dissipation and spreading mechanism for such devices.

### I. Formation of Thermal Management Devices

Reference will now be made in detail to the method of forming the thermal management devices. The thermal management devices and various exemplary designs will be subsequently described.

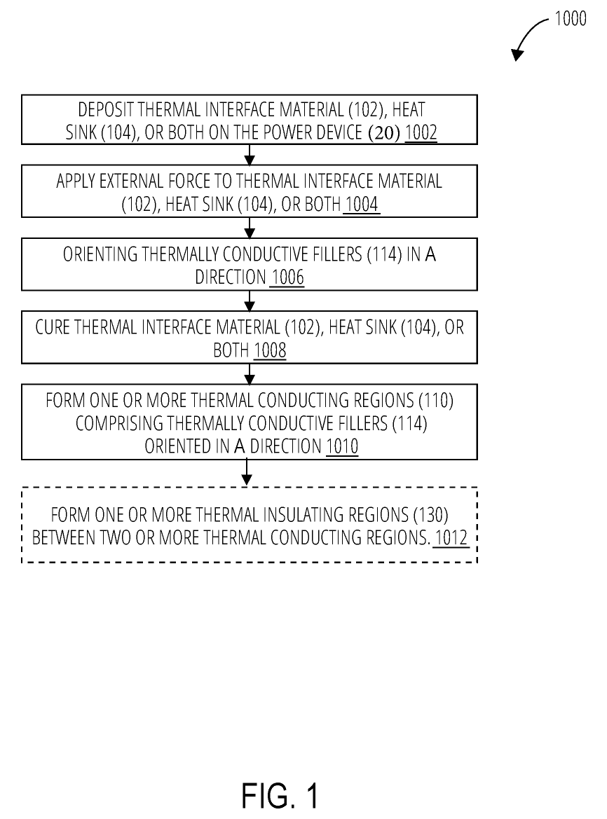

Referring to FIG. 1, a method 1000 of forming the thermal management device for cooling a power device 20 begins at block 1002 with depositing a thermal interface material 102, a heat sink 104, or both on the power device 20. According to embodiments, a first portion of the thermal interface material 102, the heat sink 104, or both may independently comprise a composite material. The composite material comprises a matrix material and a plurality of thermally conductive fillers 114. Details related to the composite material, the matrix material, and the thermally conductive fillers will be separately described in the paragraphs pertaining to the thermal management device.

The method 1000 continues at block 1004 with applying a first external force, at a first direction, to the first portion of thermal interface material, the heat sink, or both. As described herein, the thermal interface material 102, the heat sink 104, or both may further comprise a material responsive to an external force such that, upon applying the external force, the thermally conductive fillers are oriented in the direction of said force. The external force may include a magnetic field, an electric field, an electromagnetic field, a shear force, or combinations thereof. Multiple external forces may be applied to the thermal interface material 102, the heat sink 104, or both concurrently or consecutively.

The method 1000 then continues at block 1006 with orienting, within the first portion of the thermal interface material 102, the heat sink 104, or both, the plurality of thermally conductive fillers 114 in the first direction using the external force.

The method 1000 continues at block 1008 with curing the first portion of the thermal interface material 102, the heat sink 104, or both. The thermal interface material 102 and the heat sink 104 may be cured by any techniques recognized by those skilled in the art. In some embodiments, the thermal interface material 102 and the heat sink 104 may be independently cured by applying heat, an electro-magnetic wave radiation (e.g., ultra-violet radiation), chemical additives, or combinations thereof. The curing step leads to the fixation of the oriented thermally conductive fillers 114 in the first direction, and the formation of one or more thermal conducting regions exhibiting a first anisotropic thermal conductivity in the first direction at block 1010. In some embodiments, one or more thermal conducting regions comprising the first anisotropic thermal conductivity are independently coupled to one or more heat sources within the power device and operable to conduct heat from the heat sources.

According to embodiments, the methods 1000 may be repeated and applied to a second portion of the thermal interface material 102, the heat sink 104, or both that may also comprise a composite material 100 with a matrix material 112 and a plurality of thermally conductive fillers 114. At block 1004, a second external force may be applied to the second portion of the thermal interface material 102, the heat sink 104, or both at a second direction. In some embodiments, the second direction may be deviated from the first direction at an angle less than or equal to 90°. In some embodiments, the second direction is substantially perpendicular to the first direction. By applying the second external force, the thermally conductive fillers are oriented in the second direction within the second portion of the thermal interface material 102, the heat sink 104, or both. Curing the second portion of the thermal interface material 102, the heat sink 104, or both at block 1008 forms one or more thermal conducting regions comprising a second anisotropic thermal conductivity in the second direction at block 1010. In some embodiments, one or more thermal conducting regions comprising the second anisotropic thermal conductivity are independently coupled to one or more thermal conducting regions comprising the first anisotropic thermal conductivity and operable to spread heat from the heat sources through the thermal conducting regions comprising the first anisotropic thermal conductivity.

Optionally, according to embodiments, the methods 1000 may further include curing a third portion of the thermal interface material 102, the heat sink 104, or both to form one or more thermal insulating regions 130 at block 1012. In some embodiments, the third portion of the thermal interface material 102, the heat sink 104, or both independently comprise a thermal insulating material. The third portion of the thermal interface material 102, the heat sink 104, or both are substantially free of thermally conductive fillers or other thermal conducting materials. Details related to the thermal insulating materials will be separately described in the paragraphs pertaining to the thermal management device.

In some embodiments, one or more thermal insulating regions are independently disposed between two or more thermal conducting regions comprising the first anisotropic thermal conductivity or the second anisotropic thermal conductivity and form one or more thermal barriers to reduce thermal interference between two or more thermal conducting regions.

It should be understood that the sequence of forming the thermal conducting regions comprising the first anisotropic thermal conductivity, the thermal conducting regions comprising the second anisotropic thermal conductivity, and the thermal insulating regions is not limited to the embodiments disclosed and described herein and may be carried out in any order suitable for a particular thermal management design.

The method of forming a thermal management device as disclosed and described herein may be integrated with an additive manufacturing process, including a three-dimensional printing process. (Herein after, the “AM workflow”.) As discussed herein, the AM workflow provides additional flexibility in a thermal management design and permits the formation of a thermal management device with designed anisotropic thermal conductivity to enhance the individual heat transfer efficiency for each component and improve the overall heat transfer efficiency and performance of the highly integrated power device.

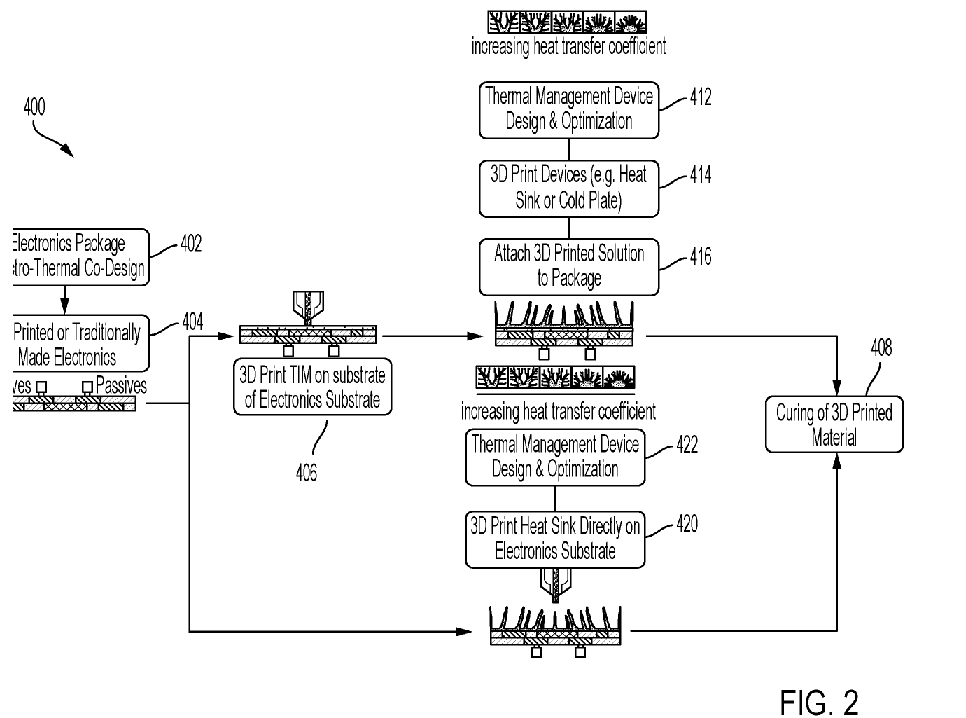

According to embodiments, the thermal interface material, the heat sink, or both may be independently deposited by a three-dimensional printing process, as shown in the example AM workflow 400 of FIG. 2. The AM workflow 400 may begin at block 406 with three-dimensional printing the thermal interface material comprising a composite material, as disclosed and described herein, on to a power device. The power device may be previously formed by a conventional process or a three-dimensional printing process at block 404. The AM workflow continues at block 416 with attaching a heat sink to the thermal interface material. It should be understood that the heat sink may be separately designed according to a thermal management design and optimization plan to increase heat transfer coefficient at block 412 and formed by a three-dimensional printing process or other conventional processes recognized by those skilled in the art at block 414. Then, the thermal interface material may be post-processed and cured at block 408, according to the method 1000 described herein and FIG. 1, to form one or more thermal conducting regions and/or one or more thermal insulating regions, as disclosed and described herein.

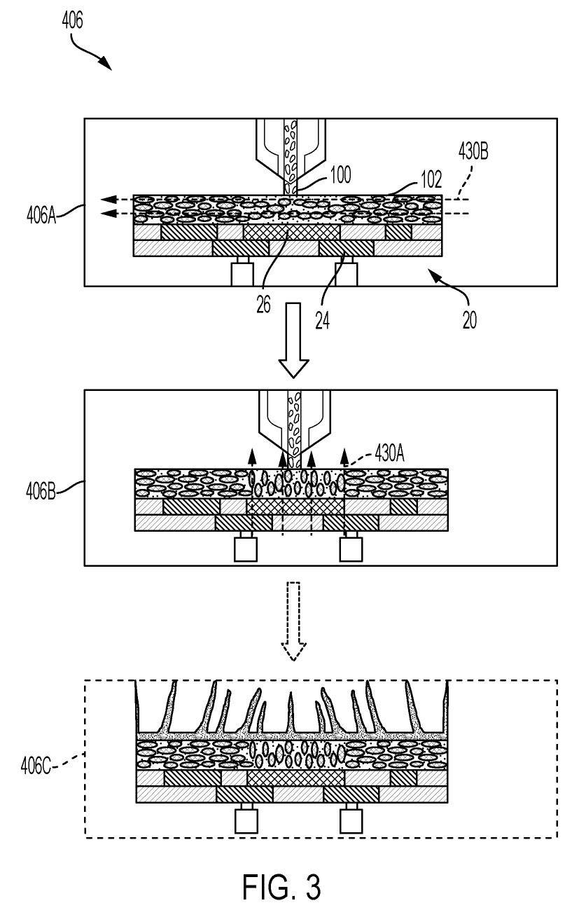

Referring to FIG. 3, an example integration of method 1000 in the AM workflow at block 406 is depicted in detail. Beginning at block 406A, an extruder extrudes a filament or a resin of a composite material 100 for a thermal interface material 102, as disclosed and described herein, on to a power device 20. The power device 20 has a heat source 26 and circuit lines 24. An external force 430B is applied in a direction substantially parallel to the power device. The external force 430B causes the thermally conductive fillers to orient substantially parallel to the power device. Proceed to block 406B, where an external force 430A is subsequently applied in a direction substantially perpendicular to the power device in a region above the heat source 26. The external force 430A causes the thermally conductive fillers in the region above the heat source to orient substantially perpendicular to the power device. The steps of 406A and/or 406B may be repeated in any other according to a thermal management design. Once the thermal interface material has been patterned with thermal conducting regions and/or thermal insulating regions according to the thermal management design, a heat sink is deposited on to the thermal interface material at block 406C.

Referring back to FIG. 2, in some embodiments, the AM workflow may begin at block 420 with three-dimensional printing heat sink comprising a composite material, as disclosed and described herein, on to the power device. Then, referring back to FIG. 1, the heat sink may be post-processed and cured at block 408, according to the method 1000, to form one or more thermal conducting regions and/or one or more thermal insulating regions, as disclosed and described herein. In some embodiments, the heat sink may be printed and post-processed according to a thermal management device design and optimization plan developed at block 422.

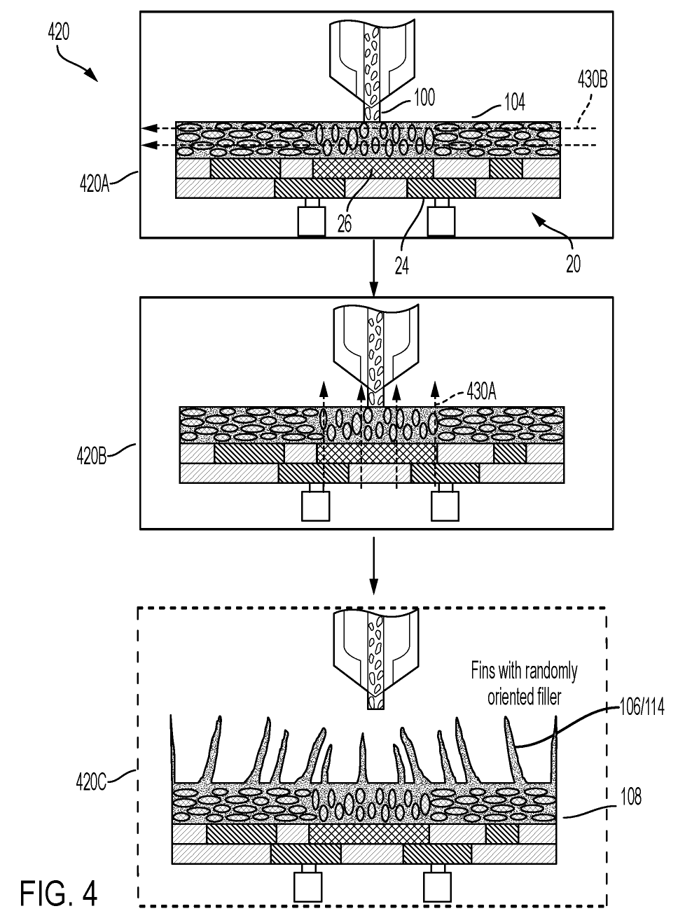

Referring to FIG. 4, another example integration of method 1000 in the AM workflow at block 420 is depicted in detail. Beginning at block 420A, an extruder extrudes a filament or a resin of a composite material 100 for the heat sink 104, as disclosed and described herein, on to a power device 20. The power device 20 has a heat source 26 and circuit lines 24. An external force 430B is applied in a direction substantially parallel to the power device. The external force 430B causes the thermally conductive fillers to orient substantially parallel to the power device. Proceed to block 420B, where an external force 430A is subsequently applied in a direction substantially perpendicular to the power device in a region above the heat source 26. The external force 430A causes the thermally conductive fillers in the region above the heat source to orient substantially perpendicular to the power device. The steps of 420A and/or 420B may be repeated in any other according to a thermal management design. Once a heat sink base 108 has been patterned with thermal conducting regions and/or thermal insulating regions according to the thermal management design, referring back to FIG. 2, the heat sink may be cured according to block 408. In some embodiments, as shown in block 420C, the heat sink may comprise fins 106, and it is contemplated the fins 106 may also comprise thermally conductive fillers 114. In some embodiments, the thermally conductive fillers within the fins 106 may be randomly oriented or oriented along the length of the fins. In some embodiments, the fins 106 may be substantially free of the thermal conductive fillers 114.

### II. Thermal Management Devices and Example Designs

Reference will now be made in detail to the thermal management devices. Example designs of the thermal management devices will be subsequently described.

According to embodiments, a thermal management device for cooling a power device may include a thermal interface material, a heat sink, or both. The thermal interface material, the heat sink, or both may independently have one or more thermal conducting regions. Each thermal conducting region independently comprises a composite material. The composite material includes a matrix material and a plurality of thermally conductive fillers. For each thermal conducting region, the plurality of thermally conductive fillers is oriented in a direction, generating an anisotropic thermal conductivity. Furthermore, for each thermal conducting region, the plurality of thermally conductive fillers are thermally coupled to form a plurality of thermal conducting paths. These thermal conducting paths are operable to conduct (e.g. dissipate or spread) heat generated by one or more heat sources of the power device.

In some embodiments, a portion of the thermal conducting regions may be a first thermal conducting region thermally coupled to the heat source. The thermally conductive fillers within the first thermal conducting region are oriented to cause anisotropic thermal conductivity in a first direction and form thermal conducting paths that are operable to dissipate heat generated by the heat source in the first direction. In some embodiments, a portion of the thermal conduction regions may be a second thermal conducting region thermally coupled to a first thermal conducting region. The thermally conductive fillers within the second thermal conducting region are oriented to cause anisotropic thermal conductivity in a second direction and form thermal conducting paths that are operable to spread heat generated by the heat source through the first conducting region in the second direction. The second direction may be deviated from the first direction at an angle less than or equal to 90°. In some embodiments, the second direction is substantially perpendicular to the first direction.

For each thermal conducting region, the shape and dimension are not particular limited and may vary according to a thermal management design and optimization plan and the requirements of a heat-generating component. In some embodiments, the shape and dimension of a thermal conducting region may conform to the shape and dimension of a surface of the heat source, to which the thermal conducting region is coupled. In some embodiments, each thermal conducting region may have a minimum dimension from 1mm to 5 mm, such as from 1 mm to 1.5 mm, from 1 mm to 2 mm, from 1 mm to 2.5 mm, from 1 mm to 3 mm, from 1 mm to 3.5 mm, from 1 mm to 3.5 mm, from 1 mm to 4 mm, from 1 mm to 4.5 mm, from 1.25 mm to 1.75 mm, from 1.25 mm to 2.25 mm, from 1.25 mm to 2.75 mm, from 1.25 mm to 3.25 mm, from 1.25 mm to 3.75 mm, from 1.25 mm to 4.25 mm, from 1.25 mm to 4.75 mm, from 1.5 mm to 2 mm, from 1.5 mm to 2.5 mm, from 1.5 mm to 3 mm, from 1.5 mm to 3.5 mm, from 1.5 mm to 4 mm, from 1.5 mm to 4.5 mm, from 1.5 mm to 5 mm, from 1.75 mm to 2.25 mm, from 1.75 mm to 2.75 mm, from 1.75 mm to 3.25 mm, from 1.75 mm to 3.75 mm, from 1.75 mm to 4.25 mm, from 1.75 mm to 4.75 mm, from 2 mm to 2.5 mm, from 2 mm to 3 mm, from 2 mm to 3.5 mm, from 2 mm to 4 mm, from 2 mm to 4.5 mm, from 2 mm to 5 mm, from 2.25 mm to 2.75 mm, from 2.25 mm to 3.25 mm, from 2.25 mm to 3.75 mm, from 2.25 mm to 4.25 mm, from 2.25 mm to 4.75 mm, from 2.5 mm to 3 mm, from 2.5 mm to 3.5 mm, from 2.5 mm to 4 mm, from 2.5 mm to 4.5 mm, from 2.5 mm to 5 mm, from 2.75 mm to 3.25 mm, from 2.75 mm to 3.75 mm, from 2.75 mm to 4.25 mm, from 2.75 mm to 4.75 mm, from 3 mm to 3.5 mm, from 3 mm to 4 mm, from 3 mm to 4.5 mm, from 3 mm to 5 mm, from 3.25 mm to 3.75 mm, from 3.25 mm to 4.25 mm, from 3.25 mm to 4.75 mm, from 3.5 mm to 4 mm, from 3.5 mm to 4.5 mm, from 3.5 mm to 5 mm, from 3.75 mm to 4.25 mm, from 3.75 mm to 4.75 mm, from 4 mm to 4.5 mm, from 4 mm to 5 mm, from 4.25 mm to 4.75 mm, from 4.5 mm to 5 mm, or any combinations of the previous ranges or smaller ranges therein.

For each thermal conducting region, the composite material and its composition may be substantially the same or different. In some embodiments, the thermal interface material comprises the plurality of thermal conducting regions. As non-limiting examples, for each thermal conducting region within the thermal interface material, the matrix material may be independently selected from the group consisting of polylactic acids (PLA), acrylonitrile butadiene styrenes (ABS), acrylonitrile styrene acrylates (ASA), polycarbonates (PC), polyphenylene sulfides (PPS), polyetheretherketones (PEEK), polydimethylsiloxanes (PDMS), and combinations thereof.

In some embodiments, the heat sink comprises the plurality of thermal conducting regions. For each thermal conducting region within the heat sink, the matrix material may be independently selected from the group consisting of steels, irons, aluminum, nickel, chromium, titanium, tungsten, molybdenum, copper, alloys thereof, and combinations thereof. As non-limiting examples, the matrix material of a heat sink may include tool steels, stainless steels, aluminum alloy such as AlSi10Mg and AlSi12, nickel-chromium-based alloys such as Inconel, titanium alloy such as Ti64, copper tungsten, copper molybdenum, aluminum nitride, aluminum silicon carbide, or combinations thereof.

As non-limiting examples, for each thermal conducting region, the thermally conductive fillers may be independently selected from the group consisting of Al, Cu, graphene, carbon nanotubes, boron nitride, aluminum oxide, AlN, SiC, and combinations thereof.

For efficient thermal coupling and heat transfer, in some embodiments, the thermally conductive fillers in each thermal conducting region may have a thermal conductivity from 30 to 1000 Watts per meter-Kelvin (W/m·K), such as from 30 W/m·K to 800 W/m·K, from 30 W/m·K to 600 W/m·K, from 30 W/m·K to 400 W/m·K, from 30 W/m·K to 200 W/m·K, from 50 W/m·K to 950 W/m·K, from 50 W/m·K to 750 W/m·K, from 50 W/m·K to 550 W/m·K, from 50 W/m·K to 350 W/m·K, from 50 W/m·K to 150 W/m·K, from 100 W/m·K to 1000 W/m·K, from 100 W/m·K to 800 W/m·K, from 100 W/m·K to 600 W/m·K, from 100 W/m·K to 400 W/m·K, from 100 W/m·K to 200 W/m·K, from 150 W/m·K to 950 W/m·K, from 150 W/m·K to 750 W/m·K, from 150 W/m·K to 550 W/m·K, from 150 W/m·K to 350 W/m·K, from 200 W/m·K to 1000 W/m·K, from 200 W/m·K to 800 W/m·K, from 200 W/m·K to 600 W/m·K, from 200 W/m·K to 400 W/m·K, from 250 W/m·K to 950 W/m·K, from 250 W/m·K to 750 W/m·K, from 250 W/m·K to 550 W/m·K, from 250 W/m·K to 350 W/m·K, from 300 W/m·K to 1000 W/m·K, from 300 W/m·K to 800 W/m·K, from 300 W/m·K to 600 W/m·K, from 300 W/m·K to 400 W/m·K, from 350 W/m·K to 950 W/m·K, from 350 W/m·K to 750 W/m·K, from 350 W/m·K to 550 W/m·K, from 400 W/m·K to 1000 W/m·K, from 400 W/m·K to 800 W/m·K, from 400 W/m·K to 600 W/m·K, from 450 W/m·K to 950 W/m·K, from 450 W/m·K to 750 W/m·K, from 450 W/m·K to 550 W/m·K, from 500 W/m·K to 1000 W/m·K, from 500 W/m·K to 800 W/m·K, from 500 W/m·K to 600 W/m·K, from 550 W/m·K to 950 W/m·K, from 550 W/m·K to 750 W/m·K, from 600 W/m·K to 1000 W/m·K, from 600 W/m·K to 800 W/m·K, from 650 W/m·K to 950 W/m·K, from 650 W/m·K to 750 W/m·K, from 700 W/m·K to 1000 W/m·K, from 700 W/m·K to 800 W/m·K, from 750 W/m·K to 950 W/m·K, from 800 W/m·K to 1000 W/m·K, or any combinations of the previous ranges or smaller ranges therein.

In some embodiments, the loading density of thermally conductive fillers may be from 10 wt.% to 80 wt.%, such as from 10 wt.% to 60 wt.%, from 10 wt.% to 40 wt.%, from 10 wt.% to 20 wt.%, from 20 wt.% to 70 wt.%, from 20 wt.% to 50 wt.%, from 20 wt.% to 30 wt.%, from 30 wt.% to 80 wt.%, from 30 wt.% to 60 wt.%, from 30 wt.% to 50 wt.%, from 40 wt.% to 70 wt.%, from 40 wt.% to 50 wt.%, from 50 wt.% to 80 wt.%, from 50 wt.% to 60 wt.%, from 60 wt.% to 70 wt.%, from 70 wt.% to 80 wt.%, or any combinations of the previous ranges or smaller ranges therein, measured by the total weight of the composite material in each thermal conducting region.

In some embodiments, the thermally conductive fillers may have an average minimum particle dimension from 0.1 μm to 500 μm, such as from 0.1 μm to 400 μm, from 0.1 μm to 300 μm, from 0.1 μm to 200 μm, from 0.1 μm to 100 μm, from 0.1 μm to 10 μm, from 0.1 μm to 1 μm, from 0.1 μm to 0.8 μm, from 0.1 μm to 0.6 μm from 0.1 μm to 0.4 μm, from 0.1 μm to 0.2 μm, from 0.2 μm to 450 μm, from 0.2 μm to 350 μm, from 0.2 μm to 250 μm, from 0.2 μm to 150 μm, from 0.2 μm to 50 μm, from 0.2 μm to 5 μm, from 0.2 μm to 2.5 μm, from 0.2 μm to 1 μm, from 0.2 μm to 0.9 μm, from 0.2 μm to 0.7 μm, from 0.2 μm to 0.5 μm, from 0.5 μm to 500 μm, from 0.5 μm to 400 μm, from 0.5 μm to 300 μm, from 0.5 μm to 200 μm, from 0.5 μm to 100 μm, from 0.5 μm to 10 μm, from 0.5 μm to 1 μm, from 0.5 μm to 0.8 μm, from 1 μm to 450 μm, from 1 μm to 350 μm, from 1 μm to 250 μm, from 1 μm to 150 μm, from 1 μm to 50 μm, from 1 μm to 5 μm, from 1 μm to 2.5 μm, from 10 μm to 500 μm, from 10 μm to 400 μm, from 10 μm to 300 μm, from 10 μm to 200 μm, from 10 μm to 100 μm, from 10 μm to 80 μm, from 10 μm to 60 μm, from 10 μm to 40 μm, from 10 μm to 20 μm, from 20 μm to 500 μm, from 20 μm to 400 μm, from 20 μm to 300 μm, from 20 μm to 200 μm, from 20 μm to 100 μm, from 20 μm to 80 μm, from 20 μm to 60 μm, from 20 μm to 40 μm, from 40 μm to 500 μm, from 40 μm to 400 μm, from 40 μm to 300 μm, from 40 μm to 200 μm, from 40 μm to 100 μm, from 40 μm to 80 μm, from 40 μm to 60 μm, from 60 μm to 500 μm, from 60 μm to 400 μm, from 60 μm to 300 μm, from 60 μm to 200 μm, from 60 μm to 100 μm, from 60 μm to 80 μm, from 80 μm to 500 μm, from 80 μm to 400 μm, from 80 μm to 300 μm, from 80 μm to 200 μm, from 80 μm to 100 μm, from 100 μm to 500 μm, from 100 μm to 400 μm, from 100 μm to 300 μm, from 100 μm to 200 μm, from 200 μm to 500 μm, from 200 μm to 400 μm, from 200 μm to 300 μm, from 300 μm to 500 μm, from 300 μm to 400 μm, from 400 μm to 500 μm, or any combinations of the previous ranges or smaller ranges therein.

In some embodiments, the shape of thermally conductive fillers may have an aspect ratio from 1 to 20, such as from 1 to 15, from 1 to 10, from 1 to 5, from 1 to 3, from 3 to 18, from 3 to 13, from 3 to 8, from 5 to 20, from 5 to 15, from 5 to 10, from 7 to 18, from 7 to 13, from 10 to 20, from 10 to 15, from 13 to 18, or from 15 to 20, defined as the ratio of the longest dimension to the shortest dimension of thermally conductive fillers.

The thermally conductive fillers may be oriented by applying an external force, which may include a magnetic field, an electric field, an electromagnetic field, a sheer force, or combinations thereof. Therefore, the thermal conducting devices may further comprise a material responsive to the external force such that, upon applying the external force in a direction, the thermally conductive fillers are oriented in the same direction as the external force. In some embodiments, the thermally conductive fillers may comprise a magnetic material such that the thermally conductive fillers can be oriented in response to a magnetic field. Upon applying a magnetic field, the thermally conductive fillers in each thermal conducting region are oriented along the magnetic field lines, allowing them to be thermally coupled to form thermal conducting paths along the magnetic field lines.

It is also contemplated that a portion or all of the thermal conducting regions may further comprise additional nanoparticles responsive to an external force. In some embodiments, the additional nanoparticles may be magnetic nanoparticles. Upon applying a magnetic field, the additional nanoparticles are oriented along the direction of the magnetic field lines, causing the alignment of the thermally conductive fillers in the same alignment direction of the additional nanoparticles.

As disclosed herein, in some embodiments, the thermal management device may comprise one or more thermal insulating regions that spatially separate and/or thermally decouple two or more thermal conducting regions. For example, and in one embodiment, the thermal interface material may include one or more thermal insulating region that independently comprises a thermal insulating material and is free of or substantially free of thermally conductive fillers. The thermal insulating material may be substantially the same as or different from the matrix material of the thermal conducting regions separated by the thermal insulating regions. For efficient thermal decoupling and heat insulation, in some embodiments, the thermal insulating material may have a thermal conductivity less than 0.5 Watts per meter-Kelvin (W/m·K) , such as less than 0.4 W/m·K, less than 0.3 W/m·K, less than 0.2 W/m·K, less than 0.1 W/m·K, from 0.1 W/m·K to 0.5 W/m·K, from 0.1 W/m·K to 0.4 W/m·K, from 0.1 W/m·K to 0.3 W/m·K, from 0.1 W/m·K to 0.2 W/m·K, from 0.2 W/m·K to 0.5 W/m·K, from 0.2 W/m·K to 0.4 W/m·K, from 0.2 W/m·K to 0.3 W/m·K, from 0.3 W/m·K to 0.5 W/m·K, from 0.3 W/m·K to 0.4 W/m·K, or from 0.4 W/m·K to 0.5 W/m·K. The thermal insulating region may have a minimum width from 0.5 mm to 2 mm, such as from 0.5 mm to 1.75 mm, from 0.5 mm to 1.5 mm, from 0.5 mm to 1.25 mm, from 0.5 mm to 1 mm, from 0.5 mm to 0.75 mm, from 0.75 mm to 2 mm, from 0.75 mm to 1.75 mm, from 0.75 mm to 1.5 mm, from 0.75 mm to 1.25 mm, from 0.75 mm to 1 mm, from 1 mm to 2 mm, from 1 mm to 1.75 mm, from 1 mm to 1.5 mm, from 1 mm to 1.25 mm, from 1.25 mm to 2 mm, from 1.25 mm to 1.75 mm, from 1.25 mm to 1.5 mm, from 1.5 mm to 2 mm, from 1.5 mm to 1.75 mm, or from 1.75 mm to 2 mm, measured by the minimum distance between thermal conducting regions separated by the thermal insulating region.

As non-limiting examples, the thermal insulating material in each thermal insulating region may independently comprise polylactic acids (PLA), acrylonitrile butadiene styrenes (ABS), acrylonitrile styrene acrylates (ASA), polycarbonates (PC), polyphenylene sulfides (PPS), polyetheretherketones (PEEK), polymethylsiloxanes (PDMS), and combinations thereof.

Reference will now be made in detail to the example designs of the thermal management devices.

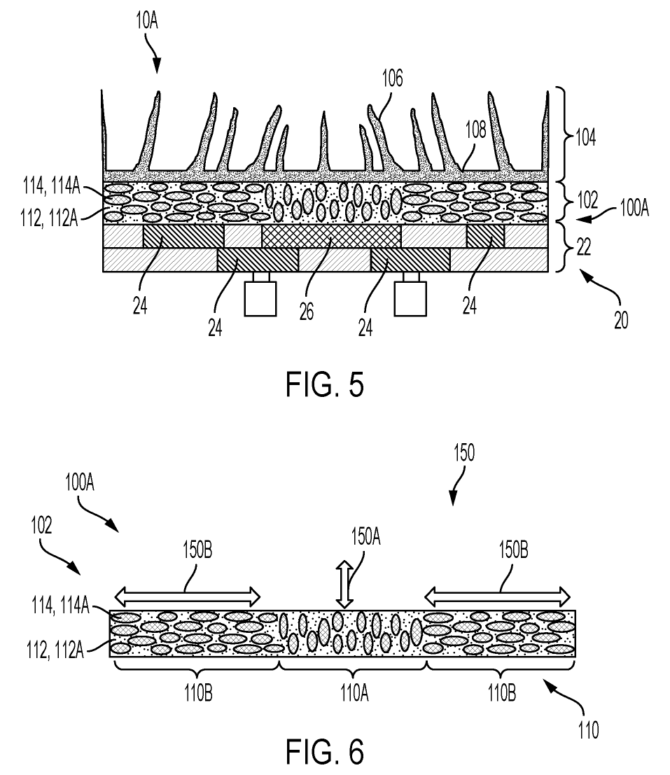

Referring to FIG. 5, an illustrative thermal management device 10A, which includes a thermal interface material 102 containing a composite material 100A, is depicted. In the illustrative thermal management device 10A, the thermal interface material 102 containing the composite material 100A is disposed between a power device 20 and a heat sink 104. The power device 20 includes a printed circuit board 22 containing a heat source 26 and multiple circuit lines 24. The heat sink 104 has a heat sink base 108 and a plurality of fins 106.

Referring to FIG. 6, the composite material 100A is depicted. The composite material 100A has a plurality of thermal conducting regions 110, including a first thermal conducting region 110A and multiple second thermal conducting regions 110B. Each thermal conducting region 110 independently has a matrix material 112 (e.g. a first matrix material 112A) and a plurality of thermally conductive fillers 114 (e.g. first thermally conductive fillers 114A). In the first thermal conducting region 110A, the first thermally conductive fillers 114A are oriented in a first direction 150A, creating anisotropic thermal conductivity in the first direction 150A in the first thermal conducting region 110A. In the second thermal conducting regions 110B, the first thermally conductive fillers 114A are oriented in a second direction 150B, creating anisotropic thermal conductivity in the second direction 150B in the second thermal conducting regions 110B.

Referring to both FIG. 5 and FIG. 6, in some embodiments the first thermal conducting region is disposed on a top surface of the heat source 26. The first direction 150A is substantially perpendicular to the top surface of the heat source 26, such that the first thermal conducting region 110A is thermally coupled to the heat source 26 and is operable to dissipate heat generated by the heat source 26 away from the heat source 26 through its top surface.

In some embodiments, the second thermal conducting regions 110B are disposed adjacent to or proximal to the first thermal conducting region 110A. The second direction 150B deviates from the first direction 150A at an angle less than or equal to 90°, such that the anisotropic thermal conductivity of each second thermal conducting region 110B deviates from that of the first thermal conducting region 110A. As a result, each second thermal conducting region 110B is thermally coupled to the first thermal conducting region 110A at an angle and is operable to spread heat generated by the heat source 26 away from the heat source 26 through the first thermal conducting region 110A. Therefore, the thermal interface material 102 containing the composite material 100A can spread the heat uniformly across the heat sink 104, allowing the efficient heat dissipation.

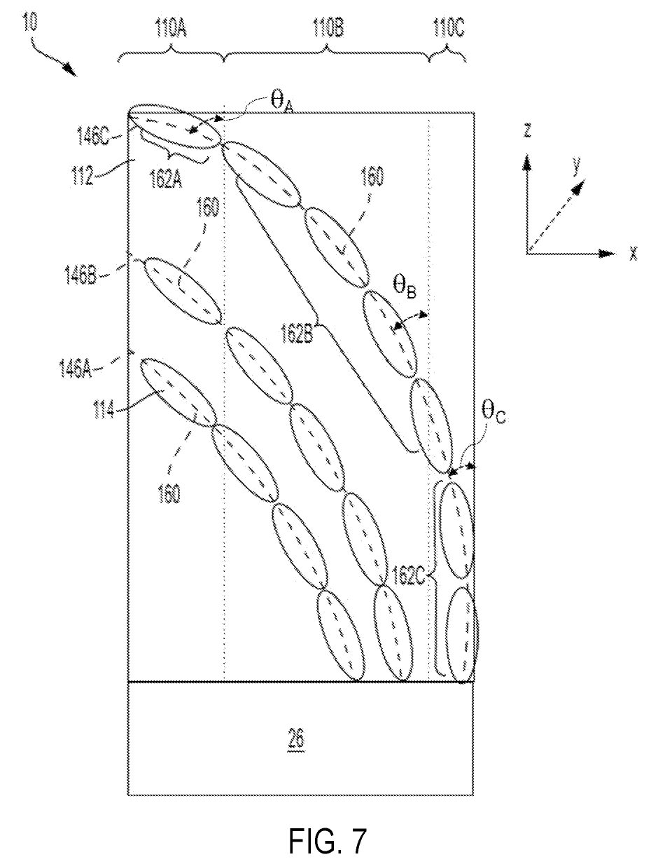

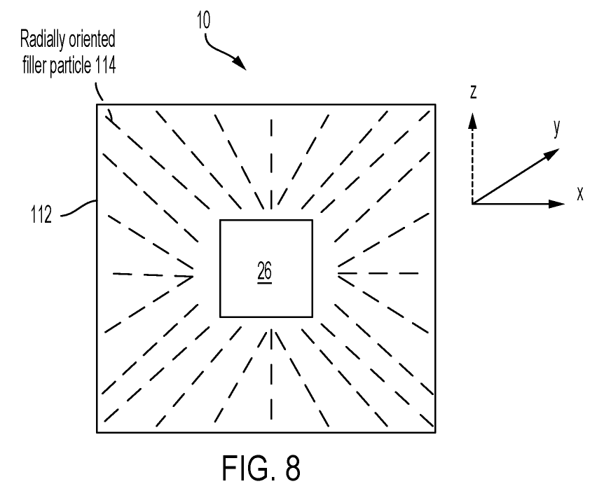

It should be noted that, the thermally conductive fillers 114 in the first thermal conducting regions 110A and the second thermal conducting regions 110B of the thermal management device 10A described in FIG. 1 other thermal management devices subsequently described, are shown to be discretely oriented perpendicular to each other for illustration purposes only and should not limit the scope of the present disclosure. As shown in FIG. 7 and FIG. 8 and described herein, those skilled would understand that the thermally conductive fillers 114 can be configured to orient at continuously varied angles in each thermal conducting region 110 or conform to a designed contour.

Referring to FIG. 7, a cross-sectional view of the alignment of thermally conductive fillers 114 in a thermal management device 10 is depicted. As discussed herein, the thermally conductive fillers 114 may be oriented by applying an external force. External forces like a magnetic field and an electric field have continuously contoured field lines 146 (e.g. 146A, 146B, and 146C). Depending on the dimensions of the thermal management device and/or the intensity of the external force, the thermally conductive fillers 114 may be oriented at continuously varied angles along the field lines 146 across multiple thermal conducting regions, such as 110A, 110B, and 110C shown in FIG. 7. For example, the thermally conductive fillers 114 in each thermal conducting region 110A, 110B, and 110C proximal to the heat source 26 are oriented at an angle θ_{C} that is substantially perpendicular to the top surface of the heat source 26, forming thermal conducting path segments 162C at the same angle θ_{C}. On the other hand, the thermally conductive fillers 114 in each thermal conducting region 110A, 110B, and 110C distal to the heat source 26 are oriented at an angle θ_{A} that is substantially parallel to the top surface of the heat source 26, forming thermal conducting path segments 162A at the same angle θ_{A}. The thermally conductive fillers disposed between the proximal end and the distal end of each thermal conducting region 110A, 110B, and 110C form thermal conducting path segments 162B oriented at an angle θ_{B} that is less than θ_{A} and greater than θ_{C}. Thermal conducting path segments 162A, 162B, and 162C are thermally coupled to form continuously contoured thermal conducting paths 160 that conform to the field lines of the applied external forces.

Referring to FIG. 8, a top view of the alignment of thermally conductive fillers 114 in an example thermal management device 10 is depicted. As discussed herein, the thermally conductive fillers 114 in each thermal conducting region are oriented along field lines of the applied external force. Therefore, in some embodiments, the applied external force may be manipulated to form different contours, causing the thermally conductive fillers to, for example, and in some embodiments, a portion of the thermal conducting regions may be coupled to a periphery of a heat source 26. The thermally conductive fillers 114 are oriented in a radially outward direction, generating a radial thermal conductivity, and thermally coupled to form a plurality of radially outward thermal conducting paths.

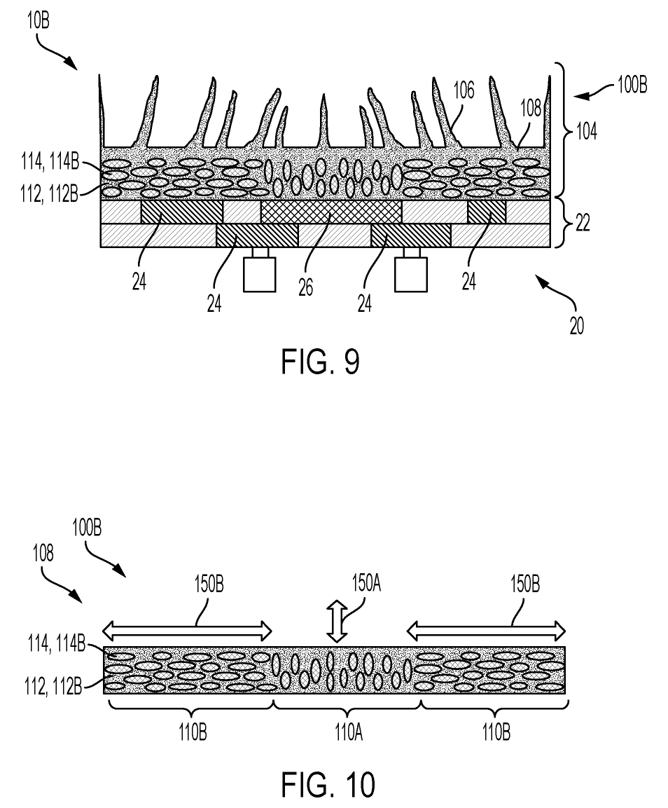

As discussed herein, the thermal management device 10 may include a heat sink 104. Referring to FIG. 9, an illustrative thermal management device 10B, which includes a heat sink 104 containing a composite material 100B, is depicted. The heat sink 104 includes a heat sink base 108 and fins 106. It is contemplated that the heat sink base 108, fins 106, or both may individually comprise the composite material 100B, including the thermally conductive fillers contained therein. As illustrated in FIG. 9, the heat sink base 108 containing the composite material 100B is disposed atop a power device 20 having a printed circuit board 22 containing a heat source 26 and a circuit line 24.

Referring to FIG. 10, the composite material 100B of the heat sink base 108 is depicted. The composite material 100B has a first thermal conducting region 110A and multiple second thermal conducting regions 110B. Each thermal conducting region 110 has a matrix material 112 (e.g. a second matrix material 112B) and a plurality of thermally conductive fillers 114 (e.g. second thermally conductive fillers 114B).

Referring to both FIG. 9 and FIG. 10, in the illustrative thermal management device 10B, the first thermal conducting region 110A is disposed on a top surface of the heat source 26. The first thermal conducting region 110A has anisotropic thermal conductivity that is substantially perpendicular to the top surface of the heat source 26 as a result of the orientation of the second thermally conductive fillers 114B within the first thermal conducting region 110A. The second thermal conducting regions 110B are disposed adjacent to or proximal to the first thermal conducting region 110A and have anisotropic thermal conductivity that is substantially parallel to the top surface of the heat source 26 as a result of the orientation of the second thermally conductive fillers 114B within the second thermal conducting regions 110B. Accordingly, each second thermal conducting region 110B is thermally coupled to the first thermal conducting region 110A and is operable to spread heat generated by the heat source 26 away from the heat source 26 through the first thermal conducting region 110A. By spreading the heat uniformly across the heat sink base 108, the heat can be efficiently dissipated through the fins 106. Furthermore, as stated herein, the fins 106 may also contain the second thermally conductive fillers 114B or other thermally conductive fillers compatible with the material or shape of the fins. In some embodiments, the thermally conductive fillers in the fins 106 may be oriented parallel to the longest dimension of the fins to enhance the dissipation of heat through the fins.

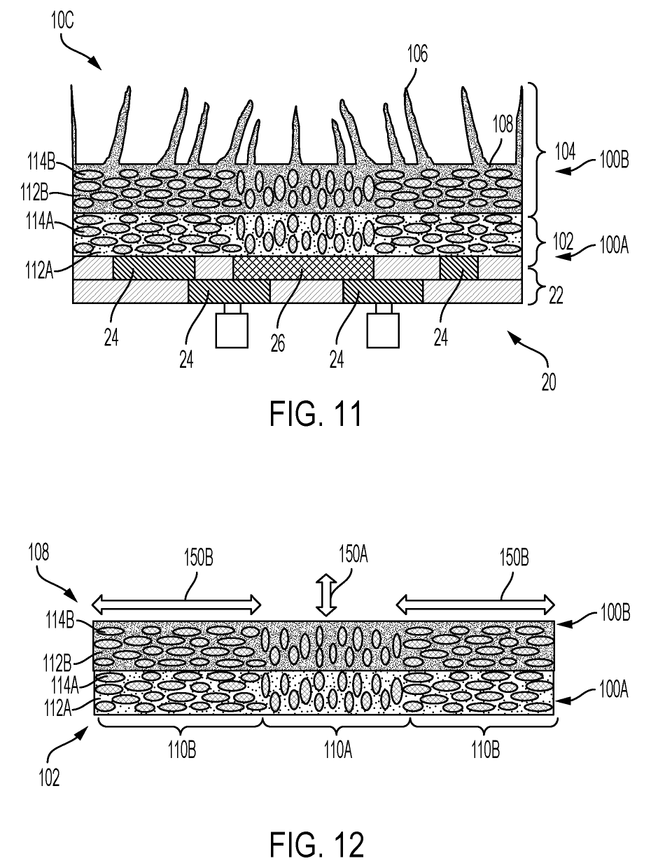

The thermal management device 10 may include both a thermal interface material 102 and a heat sink 104. Referring to FIG. 11, an illustrative thermal management device 10C, which includes a thermal interface material 102 containing a composite material 100A and a heat sink 104 containing a composite material 100B, is depicted. The heat sink 104 includes a heat sink base 108 and fins 106, and the heat sink base 108, fins 106, or both may individually comprise the composite material 100B, including the thermally conductive fillers contained therein. As shown in FIG. 11, the thermal interface material 102 is disposed between the heat sink 104 and the power device 20.

Referring to FIG. 12, the composite material 100A of the thermal interface material 102 and the composite material 100B within the heat sink base 108 are depicted. The composite materials 100A and 100B each have a first thermal conducting region 110A and multiple second thermal conducting regions 110B. Each thermal conducting region 110 has a matrix material 112 (e.g. a first matrix material 112A or a second matrix material 112B) and a plurality of thermally conductive fillers 114 (e.g. first thermally conductive fillers 114B or second thermally conductive fillers 114B). Referring to both FIG. 11 and FIG. 12, the composite materials 100A and 100B of the thermal interface material 102 and the heat sink base 108, respectively, both include a first thermal conducting region 110A having anisotropic thermal conductivity perpendicular to the top surface of the heat source 26 and multiple second thermal conducting regions 110B having anisotropic thermal conductivity parallel to the top surface of the heat source 26. This design allows heat generated from the heat source 26 to be efficiently dissipated through both the thermal interface material 102 and the heat sink base 108.

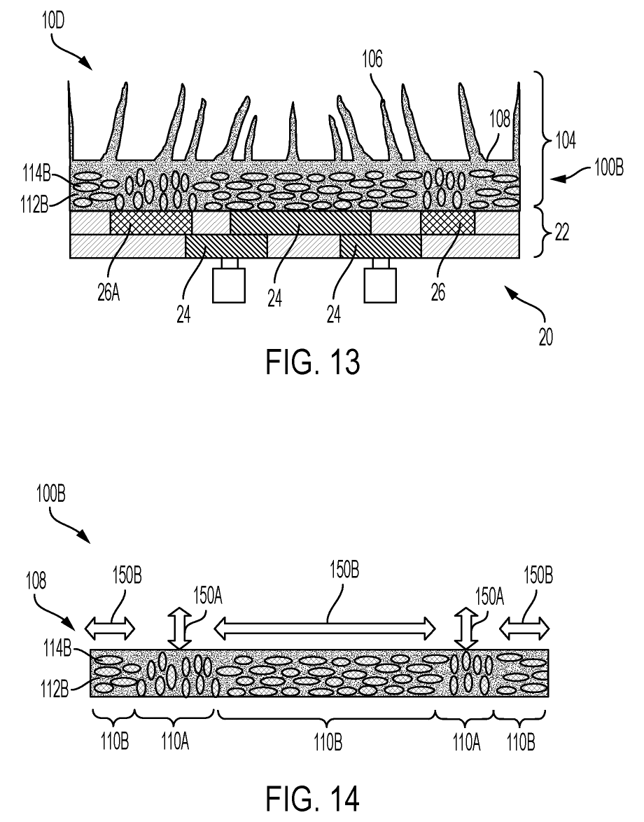

As discussed herein, a highly integrated power device 20 may contain multiple heat sources 26. Referring to FIG. 13, an illustrative thermal management device 10D for cooling a power device containing multiple heat sources 26 is depicted. In FIG. 13, the illustrative thermal management device 10D is disposed atop a power device 20 containing two heat sources 26 and 26A, and the thermal management device 10D include a heat sink 104.

Referring to FIG. 14, the composite material 100B of the heat sink 104 includes two first thermal conducting regions 110A having anisotropic thermal conductivity perpendicular to the top surface of each heat source 26 and 26A such that the heat generated from both heat sources 26 and 26A can be efficiently removed. It should be understood that, while the illustrative thermal management device 10D only includes a heat sink 104, the design concept of the thermal management device 10D is applicable to other thermal management devices (e.g. 10A and 10C) disclosed and described herein.

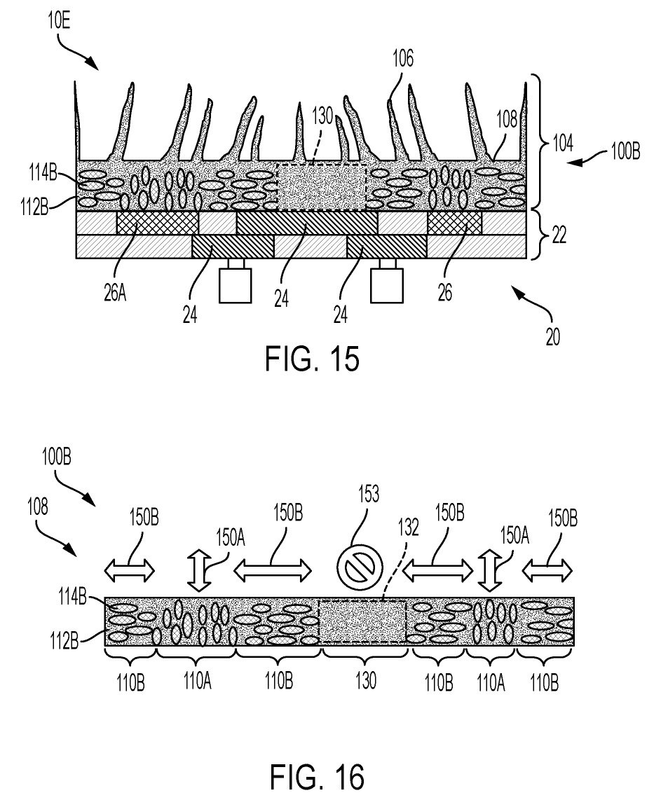

As shown in FIG. 14, a second thermal conducting region 110B is disposed between the two first thermal conducting regions 110A. In some instances, thermally decoupling of the two first thermal conducting regions for heat sources 26 and 26A may be needed to reduce thermal interference between the heat sources. Referring to FIG. 15, a thermal management device 10E with a thermal insulating region is depicted. According to embodiments, the thermal management devices 10E disclosed and described herein may further include one or more thermal insulating regions 130. Referring to FIG. 16, the thermal insulating region 130 may be configured to form a thermal barrier 153 between two or more heat sources 26 and operable to reduce thermal interference by thermally decoupling thermal conducting regions. Referring back to FIG. 15, for example, the thermal insulating region 130 may be disposed between neighboring thermal conducting regions 110 designed to conduct heat generated from two separate heat sources 26 and 26A. Disposing one or more thermal insulating regions 130 between these thermal conducting regions 110 thermally decouples these thermal conducting regions 110 and thereby creates spatially separated thermal conducting paths for the two heat sources.

As demonstrated at least through the example designs of thermal management devices herein, the methods disclosed and described herein are applicable to a wide range of thermal management designs. For example, the functionality of a three-dimensional printed manifold microchannel heat sink with complex fin geometries can be further enhanced by including anisotropic thermal conductivity according to embodiments disclosed herein. As a non-limiting example, the example thermal management designs and concepts may be integrated into the three-dimensional printed manifold microchannel heat sinks disclosed and described by U.S. Patent 11,428,478, which is hereby incorporated by reference in its entirety. Accordingly, the disclosed thermal management devices and their fabrication methods effectively address the challenges associated with the thermal management of highly integrated power devices.

Having described the subject matter of the present disclosure in detail and by reference to specific embodiments thereof, it is noted that the various details disclosed herein should not be taken to imply that these details relate to elements that are essential components of the various embodiments described herein, even in cases where a particular element is illustrated in each of the drawings that accompany the present description. Further, it will be apparent that modifications and variations are possible without departing from the scope of the present disclosure, including, but not limited to, embodiments defined in the appended claims. More specifically, although some aspects of the present disclosure are identified herein as preferred or particularly advantageous, it is contemplated that the present disclosure is not necessarily limited to these aspects.

Unless otherwise expressly stated, it is in no way intended that any method set forth herein be construed as requiring that its steps be performed in a specific order, nor that with any apparatus specific orientations be required. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

Unless otherwise defined, all technical and scientific terms used herein have the same meaning as commonly understood by one of ordinary skill in the art to which the invention belongs. The terminology used in the description herein is for describing particular embodiments only and is not intended to be limiting.

It is noted that the singular forms “a,” “an” and “the” include plural referents unless the context clearly dictates otherwise. Thus, for example, reference to “a” component includes aspects having two or more such components, unless the context clearly indicates otherwise.

It is noted that one or more of the following claims utilize the term “wherein” as a transitional phrase. For the purposes of defining the present subject matter, it is noted that this term is introduced in the claims as an open-ended transitional phrase that is used to introduce a recitation of a series of characteristics of features of the disclosed subject matter and should be interpreted in like manner as the more commonly used open-ended preamble term “comprising.”

The term “independently selected from,” as used in the specification and appended claims, is intended to mean that the referenced groups can be the same, different, or a combination thereof, unless the context clearly indicates otherwise. Thus, under this definition, the phrase “A, B, and C are independently selected from thermal plastics” would include the scenario where A, B, and C are all the same, where A, B, and C are all different, and where Aand B are the same but C is different.

All numerical ranges herein expressed in the format “from X to Y” are to be interpreted as including the endpoints X and Y and all numbers between the endpoints. Unless otherwise indicated, the numerical properties set forth in the specification and claims are approximations that may vary depending on the desired properties sought to be obtained in embodiments of the present invention. Notwithstanding that the numerical ranges and parameters setting forth the broad scope of the invention are approximations, the numerical values set forth in the specific examples are reported as precisely as possible. One of ordinary skill in the art will understand that any numerical values inherently contain certain errors attributable to the measurement techniques used to ascertain the values.

Directional terms as used herein – for example, up, down, right, left, front, back, top, bottom – are made only with reference to the figures as drawn and are not intended to imply absolute orientation.

It is noted that terms like “preferably,” “commonly,” and “typically” are not utilized herein to limit the scope of the claimed invention or to imply that certain features are critical, essential, or even important to the structure or function of the claimed invention. Rather, these terms are merely intended to highlight alternative or additional features that may or may not be utilized in a particular embodiment of the present invention.

For the purposes of describing and defining the present subject matter it is noted that the terms “substantially” and “about” are used herein to represent the inherent degree of uncertainty that may be attributed to any quantitative comparison, value, measurement, or other representation. The term “substantially” and “about” are also used herein also to represent the degree by which a quantitative representation may vary from a stated reference without resulting in a change in the basic function of the subject matter at issue. As such, it is used to represent the inherent degree of uncertainty that may be attributed to any quantitative comparison, value, measurement, or other representation, referring to an arrangement of elements or features that, while in theory would be expected to exhibit exact correspondence or behavior, may in practice embody something slightly less than exact.

For the purposes of describing and defining the present subject matter, certain features may be expressed as the “first” feature, the “second” feature, or the like. It should be understood The terms “first,” “second,” “first part,” “second part,” and the like, where used herein, do not denote any order, quantity, or importance, and are used to distinguish one element from another, unless specifically stated otherwise.

Though the invention has been described in detail and by reference to specific embodiments of the invention, it will be apparent that modifications and variations are possible without departing from the scope of the invention defined in the appended claims. More specifically, although some aspects of the present invention are identified herein as preferred or particularly advantageous, it is contemplated that the present invention is not necessarily limited to these preferred aspects of the invention.

What is claimed is:

1. A thermal management device for cooling a power device, comprising at least one of a thermal interface material and a heat sink, wherein:
the thermal interface material or the heat sink or both independently comprise one or more of thermal conducting regions; and
each thermal conducting region independently comprises a composite material comprising a matrix material and a plurality of thermally conductive fillers, wherein, for each thermal conducting region:
the plurality of thermally conductive fillers are oriented in a direction, generating an anisotropic thermal conductivity; and
the plurality of thermally conductive fillers are thermally coupled to form a plurality of thermal conducting paths, operable to conduct heat from one or more heat sources of the power device.

2. The thermal management device of claim 1, wherein, for each thermal conducting region:
the plurality of thermally conductive fillers comprise a magnetic material; or
the thermal conducting region further comprises a plurality of magnetic nanoparticles; or
both.

3. The thermal management device of claim 1, wherein:
at least one of the thermal conducting regions is a first thermal conducting region coupled to a surface of a heat source of the power device, wherein, for each first thermal conducting region:
the plurality of thermally conductive fillers are oriented in a first direction, generating a first anisotropic thermal conductivity substantially perpendicular to the surface of the heat source; and
the plurality of thermally conductive fillers are thermally coupled to form a plurality of thermal conducting paths operable to conduct heat generated by the heat source from the surface of the heat source.

4. The thermal management device of claim 3, wherein:
at least one of the thermal conducting regions is a second thermal conducting region coupled to a surface of a first thermal conducting region, wherein, for each second thermal conducting region:
the plurality of thermally conductive fillers are oriented in a second direction, generating a second anisotropic thermal conductivity deviated from the first anisotropy thermal conductivity at an angle less than or equal to 90°; and
the plurality of thermally conductive fillers are thermally coupled to form a plurality of thermal conducting paths operable to conduct heat generated by the heat source from the surface of the first thermal conducting region.

5. The thermal management device of claim 1, wherein:
a portion of the thermal conducting regions are coupled to a periphery of a heat source of the power device; and
the plurality of thermally conductive fillers of the portion of the thermal conducting regions are oriented in a radially-outward direction, generating a radial thermal conductivity, and thermally coupled to form a plurality of radially-outward thermal conducting paths.

6. The thermal management device of claim 1, wherein:
the heat sink comprises fins; and
the fins the matrix material and a plurality of thermally conductive fillers that are randomly oriented.

7. The thermal management device of claim 1, further comprising one or more thermal insulating regions, wherein:
each thermal insulating region is substantially free of thermally conductive fillers and comprises a thermal insulating material; and
when a thermal insulating region is disposed between two thermal conducting regions, the thermal insulating region forms a thermal barrier that is operable to thermally decouple the two thermal conducting regions.

8. The thermal management device of claim 7, wherein:
the power device comprises a first heat source and a second heat source;
one or more thermal insulating regions are coupled between a thermal conducting region of the first heat source and a thermal conducting region of the second heat source; and
the one or more thermal insulating regions are operable to thermally decouple the thermal conducting region of the first heat source and the thermal conducting region of the second heat source.

9. A method of forming a thermal management device for cooling a power device, comprising:
depositing a thermal interface material, a heat sink, or both on to the power device, wherein a first portion of the thermal interface material, the heat sink, or both independently comprise a composite material comprising a matrix material and a plurality of thermally conductive fillers;
applying a first external force to the first portion of the thermal interface material, the heat sink, or both;
orienting, within the first portion of the thermal interface material, the heat sink, or both, the plurality of thermally conductive fillers in a first direction;
curing the first portion of the thermal interface material, the heat sink, or both; and
thereby forming, within the first portion of the thermal interface material, the heat sink, or both, one or more thermal conducting regions comprising a first anisotropic thermal conductivity in the first direction.

10. The method of claim 9, wherein the thermal interface material, the heat sink, or both are deposited by 3D printing.

11. The method of claim 9, wherein the depositing step comprises:
depositing the thermal interface material on to the power device, wherein the thermal interface material comprises a composite material comprising a matrix material and a plurality of thermally conductive fillers.

12. The method of claim 9, wherein the depositing step comprises:
depositing the heat sink on to the power device, wherein the heat sink comprises a composite material comprising a matrix material and a plurality of thermally conductive fillers.

13. The method of claim 9, wherein:
a second portion of the thermal interface material, the heat sink, or both independently comprise a composite material comprising a matrix material and a plurality of thermally conductive fillers,
further comprising:
applying a second external force to a second portion of the thermal interface material, the heat sink, or both;
orienting, within the second portion of the thermal interface material, the heat sink, or both, the plurality of thermally conductive fillers in a second direction;
curing the second portion of the thermal interface material, the heat sink, or both; and
thereby forming, within the second portion of the thermal interface material, the heat sink, or both, one or more thermal conducting regions comprising a second anisotropic thermal conductivity in the second direction,
wherein the second direction is deviated from the first direction at an angle less than or equal to 90°.

14. The method of claim 9, wherein:
a third portion of the thermal interface material, the heat sink, or both independently comprise a thermal insulating material,
further comprising:
curing the third portion of the thermal interface material, the heat sink, or both; and
thereby forming, within the third portion of the thermal interface material, the heat sink, or both, one or more thermal insulating regions.

15. The method of claim 9, wherein the external force comprises a magnetic field, an electric field, an electromagnetic field, a sheer force, or combinations thereof.

16. The method of claim 9, wherein:
the external force comprises a magnetic field; and, for each thermal conducting region, the plurality of thermally conductive fillers comprise a magnetic material, or the thermal conducting region further comprises a plurality of magnetic nanoparticles, or both.

17. The method of claim 9, wherein the curing step comprises:
applying heat, an electro-magnetic wave radiation, chemical additives, or combinations thereof.

18. The method of claim 9, wherein:
one or more thermal conducting regions comprising the first anisotropic thermal conductivity are independently coupled to one or more heat sources within the power device.

19. The method of claim 13, wherein:
one or more thermal conducting regions comprising the second anisotropic thermal conductivity are independently coupled to one or more thermal conducting regions comprising the first anisotropic thermal conductivity.

20. The method of claim 14, wherein:
one or more thermal insulating regions are independently disposed between two or more thermal conducting regions comprising the first anisotropic thermal conductivity or the second anisotropic thermal conductivity.
